(19) United States
(12) Patent Application Publication
(10) Pub. No.: US 2023/0361055 A1
(43) Pub. Date: Nov. 9, 2023

(54) SEMICONDUCTOR DEVICE

(71) Applicant: MediaTek Singapore Pte. Ltd., Singapore (SG)

(72) Inventors: Aaron CHEN, Singapore (SG); Zhigang DUAN, Singapore (SG)

(21) Appl. No.: 18/188,630

(22) Filed: Mar. 23, 2023

Related U.S. Application Data
(60) Provisional application No. 63/339,532, filed on May 9, 2022.

(51) Int. Cl. H01L 23/58; H01L 23/66

(52) U.S. Cl. CPC H01L 23/585; H01L 23/66

(57) ABSTRACT

A semiconductor device is provided. The semiconductor device includes a semiconductor substrate, a first dielectric layer, a second dielectric layer and a conductive seal ring structure. The semiconductor substrate has a circuit region and a seal ring region surrounding the circuit region. The first dielectric layer is disposed over the seal ring region, wherein the first dielectric layer has a first dielectric constant. The second dielectric layer is disposed between the semiconductor substrate and the first dielectric layer, wherein the second dielectric layer has a second dielectric constant that is lower than the first dielectric constant. The conductive seal ring structure is disposed in the seal ring region. The conductive seal ring structure includes a first seal ring portion embedded in the first dielectric layer, wherein the first seal ring portion includes first patterns arranged periodically and discontinuously.

### CROSS REFERENCE TO RELATED APPLICATIONS

This application claims the benefit of U.S. Provisional Application No. 63/339,532, filed May 9, 2022, the entirety of which is incorporated by reference herein.

### BACKGROUND OF THE INVENTION

### Field of the Invention

The present invention relates to a semiconductor device, and, in particular, to a seal ring structure.

### Description of the Related Art

A seal ring is generally formed between scribe lines and a periphery region of integrated circuits of each die of a wafer, composed by alternatively laminating dielectric layers and metal layers, which are interconnected by vias that pass through the dielectric layers. When a wafer dicing process is performed along the scribe lines, the seal ring can block unwanted cracks in the scribe lines to the integrated circuits produced by the stress of the wafer dicing process. Also, the seal ring can block moisture, prevent damage from acid or alkaline chemicals, or diffusion of contaminating species. In the current semiconductor technology, a double seal ring structure has been developed to solve the more significant problem of cracking. However, the conventional continuous seal ring will degrade its RF performance.

Thus, a novel seal ring structure with improved RF performance is desirable.

### BRIEF SUMMARY OF THE INVENTION

An embodiment of the present invention provides a semiconductor device. The semiconductor device includes a semiconductor substrate, a first dielectric layer, a second dielectric layer and a conductive seal ring structure. The semiconductor substrate has a circuit region and a seal ring region surrounding the circuit region. The first dielectric layer is disposed over the seal ring region, wherein the first dielectric layer has a first dielectric constant. The second dielectric layer is disposed between the semiconductor substrate and the first dielectric layer, wherein the second dielectric layer has a second dielectric constant that is lower than the first dielectric constant. The conductive seal ring structure is disposed in the seal ring region. The conductive seal ring structure includes a first seal ring portion embedded in the first dielectric layer, wherein the first seal ring portion includes first patterns arranged periodically and discontinuously.

An embodiment of the present invention provides a semiconductor device. The semiconductor device includes a semiconductor substrate, a first dielectric layer, a second dielectric layer, a first seal ring portion and a second seal ring portion. The semiconductor substrate has a circuit region and a seal ring region surrounding the circuit region. The first dielectric layer is disposed over the seal ring region, wherein the first dielectric layer has a first dielectric constant. The second dielectric layer is disposed between the semiconductor substrate and the first dielectric layer, wherein the second dielectric layer has a second dielectric constant that is lower than the first dielectric constant. The first seal ring portion is disposed in the seal ring region and embedded in the first dielectric layer, wherein the first seal ring portion includes first discontinuous patterns in a top view. The second seal ring portion is disposed in the seal ring region and embedded in the second dielectric layer, wherein the second seal ring portion includes at least a second continuous pattern in the top view.

In addition, an embodiment of the present invention provides a semiconductor device. The semiconductor device includes a semiconductor substrate, a first dielectric layer, a first seal ring portion and a second seal ring portion. The semiconductor substrate has a circuit region and a seal ring region surrounding the circuit region. The first dielectric layer is disposed over the seal ring region, wherein the first dielectric layer has a first dielectric constant. The first seal ring portion is disposed in the seal ring region and embedded in the first dielectric layer, wherein the first seal ring portion includes first discontinuous patterns arranged periodically. The second seal ring portion is disposed in the seal ring region and between the first dielectric layer and the semiconductor substrate, wherein the second seal ring portion includes at least one closed-loop pattern.

### BRIEF DESCRIPTION OF THE DRAWINGS

The present invention can be more fully understood by reading the subsequent detailed description and examples with references made to the accompanying drawings, wherein:

FIG. 1 is a top view of a semiconductor device in accordance with some embodiments of the disclosure;

FIG. 2 is a cross-sectional view of a semiconductor device shown along line A-A′ in FIG. 1 in accordance with some embodiments of the disclosure;

FIGS. 3A and 3B are enlarged views of the semiconductor device in FIGS. 1 and 2 in accordance with some embodiments of the disclosure, showing the layouts of a first seal ring portion and a second seal ring portion of a seal ring structure;

FIG. 4 is an enlarged view of the semiconductor device in FIGS. 1 and 2 in accordance with some embodiments of the disclosure, showing the layout of the second seal ring portion of the seal ring structure;

FIG. 5 is a cross-sectional view of the semiconductor device shown along line A-A′ in FIG. 1 in accordance with some embodiments of the disclosure;

FIG. 6 is an enlarged view of the semiconductor device in FIGS. 1 and 5 in accordance with some embodiments of the disclosure, showing the layout of the second seal ring portion of the seal ring structure;

FIG. 7 is a cross-sectional view of the semiconductor device shown along line A-A′ in FIG. 1 in accordance with some embodiments of the disclosure;

FIG. 8 is an enlarged view of the semiconductor device in FIGS. 1 and 7 in accordance with some embodiments of the disclosure, showing the layout of the second seal ring portion of the seal ring structure;

FIG. 9 is a cross-sectional view of the semiconductor device shown along line A-A′ in FIG. 1 in accordance with some embodiments of the disclosure;

FIG. 10 is an enlarged view of the semiconductor device in FIGS. 1 and 9 in accordance with some embodiments of the disclosure, showing the layout of the second seal ring portion of the seal ring structure;

FIG. 11 is a cross-sectional view of the semiconductor device taken along line A-A′ in FIG. 1 in accordance with some embodiments of the disclosure; and

FIG. 12 is an enlarged view of the semiconductor device in FIGS. 1 and 11 in accordance with some embodiments of the disclosure, showing the layout of the second seal ring portion of the seal ring structure.

### DETAILED DESCRIPTION OF THE INVENTION

The following description is made for the purpose of illustrating the general principles of the invention and should not be taken in a limiting sense. The scope of the invention is best determined by reference to the appended claims.

The inventive concept is described fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. Also, the drawings as illustrated are only schematic and are non-limiting. In the drawings, the size of some of the elements may be exaggerated for illustrative purposes and not drawn to scale. The dimensions and the relative dimensions do not correspond to actual dimensions in the practice of the invention

Embodiments provide a seal ring structure for example, a double seal ring structure disposed in a seal ring region surrounding a circuit region. The double seal ring structure is a combo-structure including a first portion embedded in non low-k dielectric layers and a second portion below the first portion and embedded in low-k dielectric layers. The first portion of the seal ring structure comprises discrete conductive patterns arranged periodically and discontinuously along the seal region. The resistance of the first portion of the seal ring structure embedded in the non low-k dielectric layers can be increased. Therefore, the RF devices surrounded by the seal ring structure has improved performances (such as on-resistance (Ron), off-capacitance (Coff), etc.). In addition, the second portion of the seal ring structure comprises continuous patterns (or closed-loop patterns) made of conductive or dielectric material and enclosing the circuit region. Therefore, the seal ring structure can prevent moisture and ionic contamination from penetrating the RF devices.

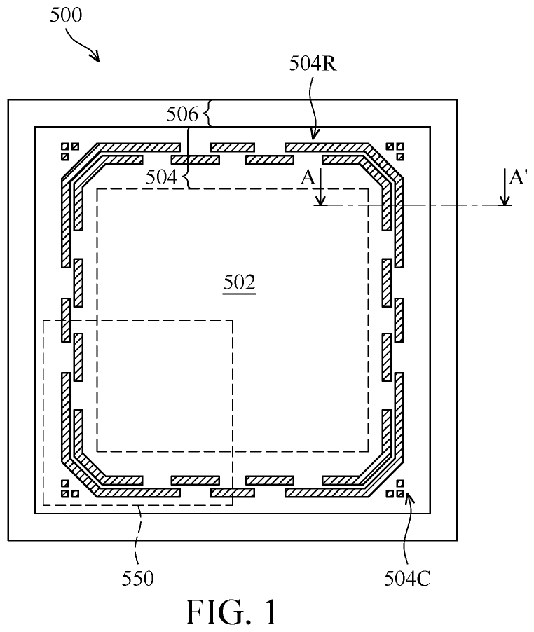

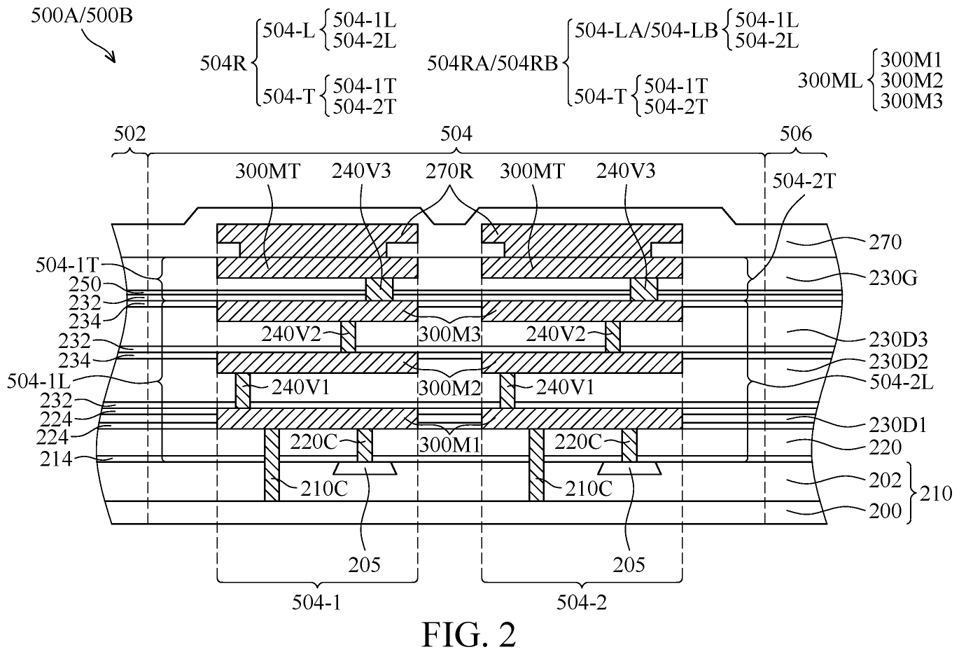

FIG. 1 is a top view of a semiconductor device 500 (including semiconductor devices 500A, 500B, 500C, 500D, 500E and 500F shown in the following FIGS. 2-12) including a seal ring structure 504R (including seal ring structures 504RA, 504RB, 504RC, 504RD, 504RE and 504RF shown in the following FIGS. 2-12) in accordance with some embodiments of the disclosure. FIG. 2 is a cross-sectional view of the semiconductor device 500A/500B shown along line A-A′ in FIG. 1 in accordance with some embodiments of the disclosure. For clearly showing the arrangements of the seal ring structure 504R, a passivation layer 270, redistribution patterns 270R and a dielectric layer 230G are not shown in FIG. 1.

As shown in FIGS. 1 and 2, the semiconductor device 500A/500B includes a semiconductor substrate 200, dielectric layers 220, 230D1, 230D2, 230D3 and 230G and the seal ring structure 504R. As shown in FIGS. 1 and 2, the semiconductor substrate 200 has a circuit region 502, a seal ring region 504 surrounding the circuit region 502 and a scribe line region 506 surrounding the seal ring region 504. In some embodiments, the semiconductor substrate 200 may comprise silicon. In alternative embodiments, SiGe, bulk semiconductor, strained semiconductor, compound semiconductor, semiconductor-on-insulator (SOI), and other commonly used semiconductor substrates can be used for the semiconductor substrate 200. The semiconductor substrate 200 may have the desired conductivity type by implanting p-type or n-type impurities. In some embodiments, an insulating feature 202 including a buried oxide layer and shallow trench isolation (STI) features (not shown) is formed on the top of the semiconductor substrate 200. The insulating feature 202 may surround and provide physical and electrical isolation for active regions 205 on the semiconductor substrate 200. The active regions 205 may be doped with p-type dopants and/or n-type dopants. In some embodiments, the semiconductor substrate 200, the insulating feature 202 and the active regions 205 surrounded by the insulating feature 202 may collectively serve as a composite semiconductor substrate 210.

The dielectric layers 220, 230D1, 230D2, 230D3 and 230G are disposed on the circuit region 502, the seal ring region 504 and the scribe line region 506 of the semiconductor substrate 200. The dielectric layers 220, 230D1, 230D2, 230D3 and 230G are laminated vertically on the semiconductor substrate 200, from bottom to top. In this embodiment, the dielectric layer 220 may serve as an interlayer dielectric (ILD) layer 220, the dielectric layers 230D1, 230D2 and 230D3 may serve as first, second and third intermetal dielectric (IMD) layers 230D1, 230D2 and 230D3, and the dielectric layer 230G may serve as a topmost intermetal dielectric layer dielectric (IMD) layer 230G. In some embodiments, the dielectric layer 230G disposed on the dielectric layers 230D1, 230D2 and 230D3 has a first dielectric constant (k), the dielectric layers 220, 230D1, 230D2 and 230D3 disposed between the dielectric layer 230G and the semiconductor substrate 200 has a second dielectric constant (k) that is lower than the first dielectric constant (k). The dielectric layers 220, 230D1, 230D2 and 230D3 may be made of a low-k dielectric material (e.g., a dielectric constant that is less than a dielectric constant of silicon dioxide) with a dielectric constant (k) between about 2.9 and 3.8, an ultra low-k dielectric material with a dielectric constant (k) between about 2.5 and 3.9 and/or an extreme low-k (ELK) dielectric material with a dielectric constant (k) less than about 2.5. For example, the dielectric layers 220, 230D1, 230D2 and 230D3 may include carbon doped oxide, porous carbon doped silicon dioxide, a polymer such as polyimide or silicon oxycarbide polymer (SiOC), or combinations thereof. In addition, the dielectric layer 230G may be made of a non low-k dielectric material with a dielectric constant (k) greater than about 3.8. For example, the dielectric layer 230G may include silicon oxide, silicon oxynitride, un-doped silicate glass (USG), borosilicate glass (BSG), phosphoric silicate glass (PSG), borophosphosilicate glass (BPSG), fluorinated silicate glass (FSG), or a combination thereof. In some embodiments, the dielectric layer 230G is formed by plasma enhanced CVD (PECVD). It is noted that the number of (low-k) dielectric layers 220, 230D1, 230D2 and 230D3 and the number of (non low-k) dielectric layer 230G are defined by the costumer design and the scope of the invention is not limited.

In some embodiments, the semiconductor device 500A/500B further includes etch stop layers 214, 224, 232 and 234 disposed between the composite semiconductor substrate 210 and the dielectric layers 220, 230D1, 230D2, 230D3 and 230G. For example, the etch stop layer 214 (also referred to as a contact etch stop layer (CESL)) is disposed between the dielectric layer 220 and the composite semiconductor substrate 210. The etch stop layer 224 is disposed between the dielectric layers 220 and 230D1. The etch stop layers 224 and 232 is disposed between the dielectric layers 230D1 and 230D2. The etch stop layers 232 and 234 is disposed between the dielectric layers 230D2 and 230D3 and between the dielectric layers 230D3 and 230G. The etch stop layers 214, 224, 232 and 234 include a dielectric material that is different than the dielectric material of dielectric layers 220, 230D1, 230D2, 230D3 and 230G. For example, if the dielectric layers 220, 230D1, 230D2, 230D3 include a low-k dielectric material, the etch stop layers 214 include silicon and nitrogen, such as silicon nitride (SiN), silicon oxynitride (SiON) or other applicable dielectric materials. The etch stop layer 224 may include silicon carbide (SiC), the etch stop layer 232 may include silicon nitride (SiN), and the etch stop layer 234 may include tetraethylorthosilicate (TEOS).

In some embodiments, the semiconductor device 500A/500B further includes a dielectric liner layer 250 disposed on the dielectric layer 230D3 and the etch stop layers 232 and 234, and between the dielectric layer 230D3 and 230G. In some embodiments, the dielectric liner layer 250 is made of a dielectric material that is different from the dielectric layer 230G, such as silicon nitride (SiN) or other applicable dielectric materials.

As shown in FIGS. 1 and 2, the seal ring structure 504R is disposed on the semiconductor substrate 200 and in the seal ring region 504. The seal ring structure 504R includes an inner seal ring portion 504-1 and an outer seal ring portion 504-2 separated from each other. The inner seal ring portion 504-1 surrounds the circuit region 502, and the outer seal ring portion 504-2 surrounds the inner seal ring portion 504-1. Also, the outer seal ring portion 202 is surrounded by the scribe line 506. The inner seal ring portion 504-1 and the outer seal ring portion 504-2 may be electrically connected to dope region (not shown) in the active regions 205 on the semiconductor substrate 200, respectively. The inner seal ring portion 504-1 and the outer seal ring portion 504-2 both embedded in the dielectric layers 220, 230D1, 230D2, 230D3 and 230G. The inner seal ring portion 504-1 and the outer seal ring portion 504-2 are both include contact plugs 210C and 220C, vias 240V1, 240V2 and 240V3 and conductive layer patterns (e.g., metal layer patterns) 300M1, 300M2, 300M3 and 300MT. The contact plugs 210C (or the contact plug 220C), the vias 240V1, 240V2 and 240V3 are alternately arranged with and electrically connected to the conductive layer patterns 300M1, 300M2, 300M3 and 300MT. In each of the inner seal ring portion 504-1 and the outer seal ring portion 504-2, the contact plug 210C passing through the dielectric layers 220 and 230D1 is connected to the semiconductor substrate 200 and the conductive layer pattern 300M1 embedded in the dielectric layer 230D1. The contact plug 220C passing through the dielectric layer 220 is connected to the active region 205 and the conductive layer pattern 300M1. The via 240V1 passing through the dielectric layer 230D2 is connected to the conductive layer pattern 300M1 embedded in the dielectric layer 230D1 and the conductive layer pattern 300M2 embedded in the dielectric layer 230D2. The via 240V2 passing through the dielectric layer 230D3 is connected to the conductive layer pattern 300M2 embedded in the dielectric layer 230D2 and the conductive layer pattern 300M3 embedded in the dielectric layer 230D3. The via 240V3 passing through the dielectric layer 230G is connected to the conductive layer pattern 300M3 embedded in the dielectric layer 230D3 and the conductive layer pattern 300MT embedded in the dielectric layer 230G. In this embodiment, the conductive layer pattern 300MT may be also referred to as a top metal layer pattern 300MT. The conductive layer pattern 300M3 may be also referred to as a next-to-top metal layer pattern 300M3, and so on. The conductive layer patterns 300M1, 300M2 and 300M3 may also serve as lower metal layer patterns 300ML. It is noted that the number of contact plugs 210C and 220C, vias 240V1, 240V2 and 240V3 and conductive layer patterns 300M1, 300M2, 300M3 and 300MT are defined by the costumer design and the scope of the invention is not limited.

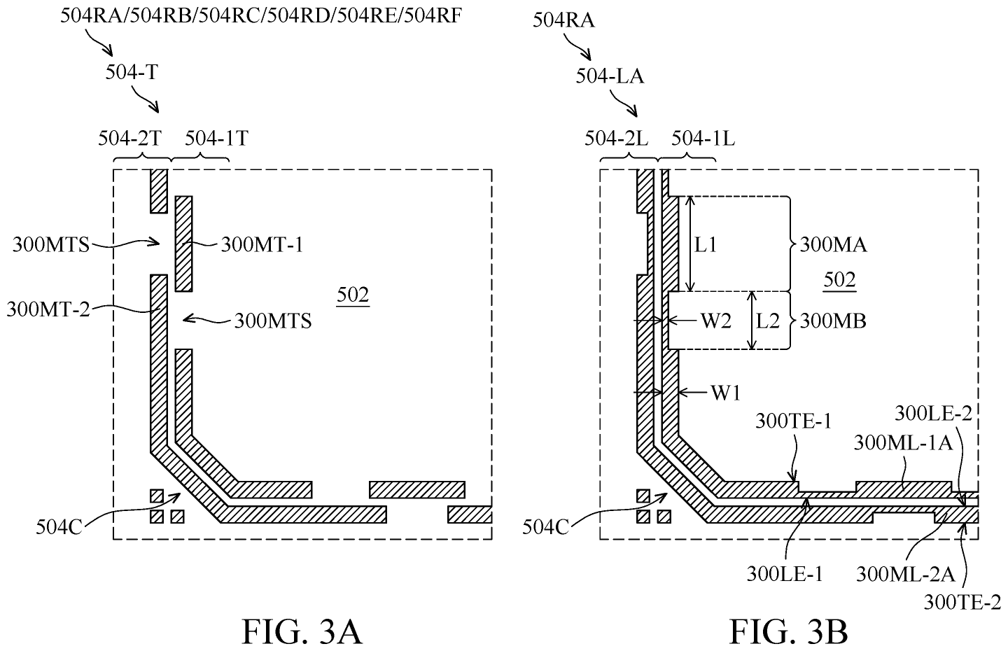

In some embodiments, the seal ring structure 504R includes a first seal ring portion 504-T embedded in the (non low-k) dielectric layer 230G and a second seal ring portion 504-L (including second seal ring portions 504-LA, 504-LB, 504-LC and 504-LD shown in FIGS. 3B, 4, 6, 8, 10 and 12) embedded in the (low-k) dielectric layers 220, 230D1, 230D2 and 230D3. The first seal ring portion 504-T (including the conductive layer pattern 300MT and the via 240V3) is electrically connected to the second seal ring portion 504-L (including the lower metal layer patterns 300ML, the contact plugs 210C and 220C and the via 240V1 and 240V2) using the vias 240V3 passing through the dielectric layer 230G. As shown in FIG. 2, the first seal ring portion 504-T further includes a first inner ring portion 504-1T in the inner seal ring portion 504-1 and a first outer ring portion 504-2T in the outer seal ring portion 504-2. The second seal ring portion 504-L disposed directly below the first seal ring portion 504-1T further includes a second inner ring portion 504-1L in the inner seal ring portion 504-1 and a second outer ring portion 504-2L in the outer seal ring portion 504-2. The first inner ring portion 504-1T and the second inner ring portion 504-1L surround the circuit region 502. The first outer ring portion 504-2T and the second outer ring portion 504-2L surround the first inner ring portion 504-1T and the second inner ring portion 504-1L, respectively.

As shown in FIG. 2, the semiconductor device 500A/500B further includes a redistribution layer pattern 270R and a passivation layer 270. The redistribution layer pattern 270R covers each of the inner seal ring portion 504-1 and the outer seal ring portion 504-2 of the seal ring structure 504R. The redistribution layer pattern 270R is formed on the conductive layer patterns 300MT. In some embodiments, the redistribution layer pattern 270R comprises a terminal via for redistribution layer (TMV_RDL) pattern (e.g., the lower portion of the redistribution layer pattern 270R) and an aluminum (Al) redistribution layer (AL_RDL) pattern (e.g., the upper portion of the redistribution layer pattern 270R) above the TMV_RDL pattern. The passivation layer 270 covers the redistribution layer pattern 270R and overlaps both the inner seal ring portion 504-1 and the outer seal ring portion 504-2.

FIGS. 3A and 3B are enlarged views of a region 550 of the semiconductor device 500A in FIGS. 1 and 2 in accordance with some embodiments of the disclosure, showing the layouts of the conductive layer patterns of the first seal ring portion 504-T and the second seal ring portion 504-LA of the seal ring structure 504RA. For clearly showing the layouts of the conductive layer patterns (including the top metal layer pattern 300MT and the lower metal layer patterns 300ML) of the first seal ring portion 504-T and the second seal ring portion 504-L of the seal ring structure 504R, the vias 240V1, 240V2 and 240V3 connected to the corresponding conductive layer patterns 300M1, 300M2, 300M3 and 300MT (FIG. 2) are not shown in FIGS. 3A and 3B and the following enlarged views of the semiconductor device 500. Elements of the embodiments hereinafter, that are the same or similar as those previously described with reference to FIGS. 1 and 2, are not repeated for brevity. As shown in FIG. 3A, the conductive layer patterns 300MT of the first seal ring portion 504-T comprise first patterns 300MT-1 in the first inner ring portion 504-1T and first patterns 300MT-2 in the first outer ring portion 504-2T. The first patterns 300MT-1 and 300MT-2 are strip patterns arranged periodically and discontinuously. In addition, the first patterns 300MT-1 and 300MT-2 of the first inner ring portion 504-1T and the first outer ring portion 504-2T are parallel with each other and in a staggered arrangement along the seal ring region 504. Therefore, the first patterns 300MT-1 and 300MT-2 may also serve as first discontinuous patterns 300MT-1 and 300MT-2. In some embodiments, spaces 300MTS between the first patterns 300MT-1 and 300MT-2 along the seal ring region 504 are away form a corner 504C of the seal ring region 504. In other words, the corner 504C of the seal ring region 504 is covered by only one of the first patterns 300MT-1 and only one of the first pattern 300MT-2.

As shown in FIG. 3B, the conductive layer patterns 300ML of the second seal ring portion 504-LA includes a second inner ring pattern 300ML-1A surrounding the circuit region 502 and a second outer ring pattern 300ML-2A surrounding the second inner ring pattern 300ML-1A. In some embodiments, each of the second inner ring pattern 300ML-1A and the second outer ring pattern 300ML-2A are continuous (closed-loop) patterns parallel to each other in a top view shown in FIG. 3B. Each of the second inner ring pattern 300ML-1A and the second outer ring pattern 300ML-2A includes first regions 300MA and second regions 300MB alternately arranged with and connected to the first regions 300MA. The first regions 300MA have a first width W1 crossing the seal ring region 504 and a first length L1 along the seal ring region 504. The second regions 300MB have a second width W2 crossing the seal ring region 504 and a second length L2 along the seal ring region 504. In some embodiments, the first length L1 is different from the second length L2. For example, the first length L1 is greater than the first length L1. In some other embodiments, the first length L1 is the same as the second length L2. In some embodiments, the first width W1 is the same as the second width W2. In some other embodiments, the first width W1 is different from the second width W2. In some embodiments, the second regions 300MB are disposed corresponding to the spaces 300MTS between the first patterns 300MT-1 and 300MT-2 in the top views shown in FIGS. 1, 3A and 3B. In some embodiments, the corner 504C of the seal ring region 504 is covered by the first regions 300MA of the second inner ring pattern 300ML-1A and the second outer ring pattern 300ML-1A but not the second regions 300MB of the second inner ring pattern 300ML-1A and the second outer ring pattern 300ML-1A.

As shown in FIG. 3B, the second inner ring pattern 300ML-1A has a linear edge 300LE-1 and a toothed edge 300TE-1 opposite to the linear edge 300LE-1. The second outer ring pattern 300ML-2A has a linear edge 300LE-2 and a toothed edge 300TE-2 opposite to the linear edge 300LE-2. The linear edges 300LE-1 and 300LE-2 and the toothed edge 300TE-1 and 300TE-2 are substantially extending along the seal ring region 504. In some embodiments, the linear edge 300LE-1 of the second inner ring pattern 300ML-1A is close to and parallel to the linear edge 300LE-2 of the second outer ring pattern 300ML-2A. The toothed edge 300TE-1 of the second inner ring pattern 300ML-1A is farther away from the toothed edge 300TE-2 of the second outer ring pattern 300ML-2A than the linear edge 300LE-2 of the second outer ring pattern 300ML-2A.

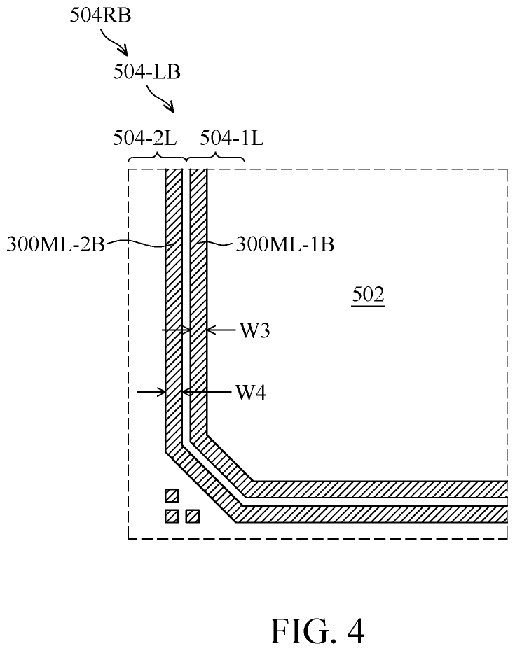

FIG. 4 is an enlarged view of the semiconductor device 500B in FIGS. 1 and 2 in accordance with some embodiments of the disclosure, showing the layout of the conductive layer patterns 300ML of a second seal ring portion 504-LB of the seal ring structure 504RB. Elements of the embodiments hereinafter, that are the same or similar as those previously described with reference to FIGS. 1, 2m 3A and 3B, are not repeated for brevity. As shown in FIG. 4, the difference between the semiconductor devices 500A and 500B is that the semiconductor device 500B includes the second seal ring portion 504-LB directly below the first seal ring portion 504-T shown in FIG. 3A. The conductive layer patterns 300ML of the second seal ring portion 504-LB includes a second inner ring pattern 300ML-1B surrounding the circuit region 502 and a second outer ring pattern 300ML-2B surrounding the second inner ring pattern 300ML-1B. In some embodiments, each of the second inner ring pattern 300ML-1B and the second outer ring pattern 300ML-2B are continuous (closed-loop) patterns parallel to each other in a top view shown in FIG. 4. The first regions 300MA has a third width W3 crossing the seal ring region 504. The second outer ring pattern 300ML-2B has a fourth width W4 crossing the seal ring region 504. In some embodiments, the third width W3 is the same as the fourth width W4.

In some embodiment, the conductive layer patterns 300MT of the first ring portion 504-T of the seal ring structures 504RA and 504RB (also serve as conductive seal ring structures 504RA and 504RB) include the first (discontinuous) patterns 300MT-1 and 300MT-2 arranged periodically and discontinuously. The first (discontinuous) patterns 300MT-1 and 300MT-2 may increase the resistance of the first ring portion 504-T of the seal ring structures 504RA and 504RB embedded in the non low-k dielectric layer (the dielectric layer 230G), thereby improving RF performances of the RF devices (not shown) disposed in the circuit region 502. In addition, the conductive layer patterns 300ML of the second seal ring portions 504-LA and 504-LB include the second inner ring pattern (such as the second inner ring patterns 300ML-1A, 300ML-1B) and the second outer ring pattern (such as the second outer ring patterns 300ML-2A, 300ML-2B) surrounding the circuit region 502. Each of the second inner ring patterns 300ML-1A, 300ML-1B and the second outer ring patterns 300ML-2A, 300ML-2B is a continuous (closed-loop) conductive pattern in the top views shown in FIGS. 3B and 4 to prevent contaminants such as chemicals, moisture, corrosive material or etc. from penetrating into the circuit region 502 and preventing cracks from propagating into the circuit region 502 in the die-sawing process. Therefore, the RF devices (not shown) disposed in the circuit region 502 surrounded by the seal ring structures 504RA and 504RB has improved RF performances (such as on-resistance (Ron), off-capacitance (Coff), etc.) and prevent moisture and ionic contamination from penetrating the RF devices.

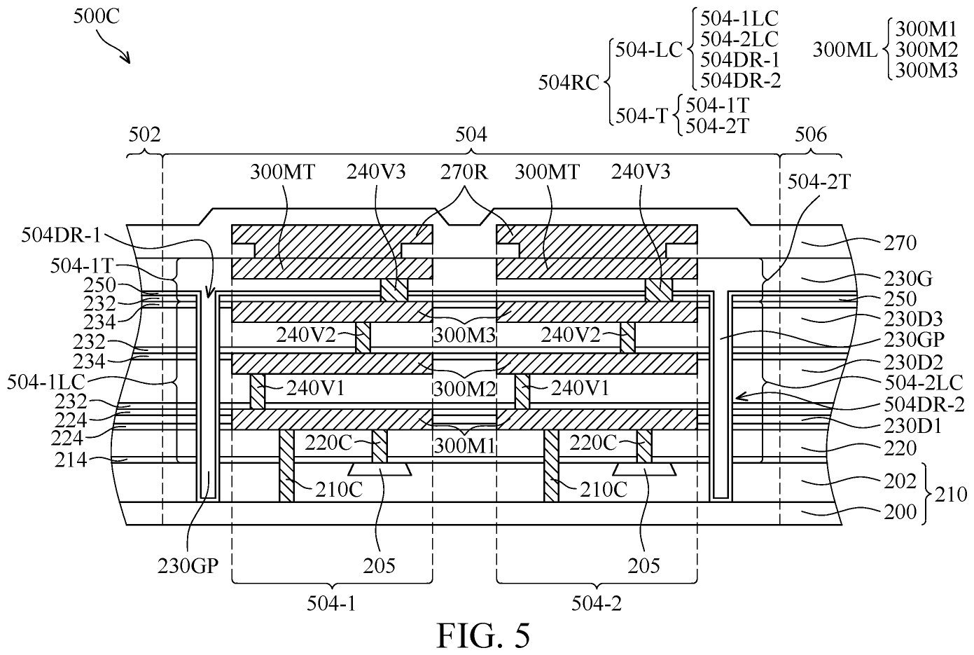

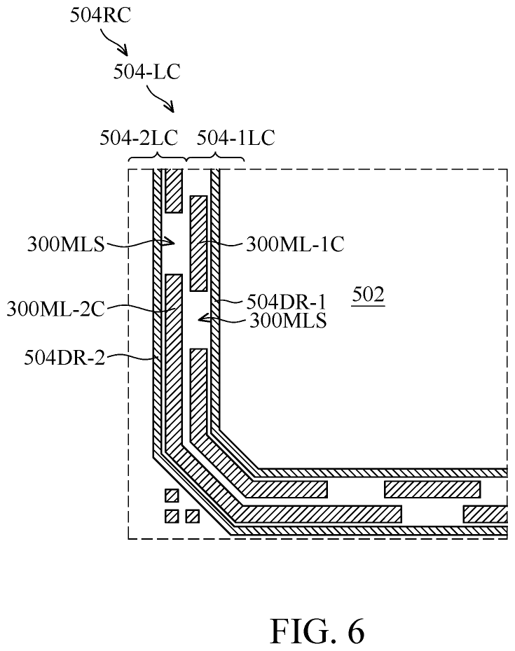

FIG. 5 is a cross-sectional view of the semiconductor device 500C shown along line A-A′ in FIG. 1 in accordance with some embodiments of the disclosure. FIG. 6 is an enlarged view of the region 550 of the semiconductor device 500C in FIGS. 1 and 5 in accordance with some embodiments of the disclosure, showing the layout of a second seal ring portion 504-LC of the seal ring structure 504RC. Elements of the embodiments hereinafter, that are the same or similar as those previously described with reference to FIGS. 1, 2, 3A, 3B and 4, are not repeated for brevity. As shown in FIGS. 5 and 6, the difference between the semiconductor devices 500A and 500C is that the semiconductor device 500C includes the second seal ring portion 504-LC directly below the first seal ring portion 504-T shown in FIG. 3A. The second seal ring portion 504-LC includes the conductive layer patterns 300MT including second patterns 300ML-1C in the second inner ring portion 504-1LC, second patterns 300ML-2C in the second outer ring portion 504-2LC, and further includes dielectric patterns including dielectric seal ring structures 504DR-1 and 504DR-2. The second inner ring portion 504-1LC surrounds the circuit region 502, and the second outer ring portion 504-2LC surrounds the second inner ring portion 504-1LC. In some embodiments, the shapes and the arrangements of the second patterns 300ML-1C and 300ML-2C of the second seal ring portion 504-LC are similar to those of the first patterns 300MT-1 and 300MT-2 of the first seal ring portion 504-T. For example, the second patterns 300ML-1C and 300ML-2C are strip patterns arranged periodically and discontinuously. In addition, the second patterns 300ML-1C and 300ML-2C are parallel with each other and in a staggered arrangement along the seal ring region 504. Therefore, the second patterns 300ML-1C and 300ML-2C may also serve as second discontinuous patterns 300ML-1C and 300ML-2C. In some embodiments, spaces 300MLS between the second patterns 300ML-1C and 300ML-2C along the seal ring region 504 are arranged corresponding to the spaces 300MTS between the first patterns 300MT-1 and 300MT-2 in the top views shown in FIGS. 1, 3A and 5.

As shown in FIGS. 5 and 6, the dielectric seal ring structures 504DR-1 and 504DR-2 are disposed in the seal ring region 504 and below the first seal ring portion 504-T of the seal ring structure 504RC. The dielectric seal ring structures 504DR-1 and 504DR-2 pass through the (low-k) dielectric layers 220, 230D1, 230D2 and 230D3 but do not pass through the (non low-k) dielectric layer 230G. In some embodiments, the dielectric seal ring structures 504DR-1 and 504DR-2 are continuous (closed-loop) patterns parallel to each other in a top view shown in FIG. 6. The dielectric seal ring structure 504DR-2 surrounds the second outer ring portion 504-2LC. In addition, the dielectric seal ring structure 504DR-1 is surrounded by the second inner ring portion 504-1LC. Each of the seal ring structures 504DR-1 and 504DR-2 includes a dielectric pillar 230GP and the dielectric liner layer 250. The dielectric pillar 230GP extends from the dielectric layer 230G to the semiconductor substrate 200. In some embodiments, the dielectric pillar 230GP is a portion of the (non low-k) dielectric layer 230G. The dielectric liner layer 250 surrounds the dielectric pillar 230GP and in contact with the semiconductor substrate 200.

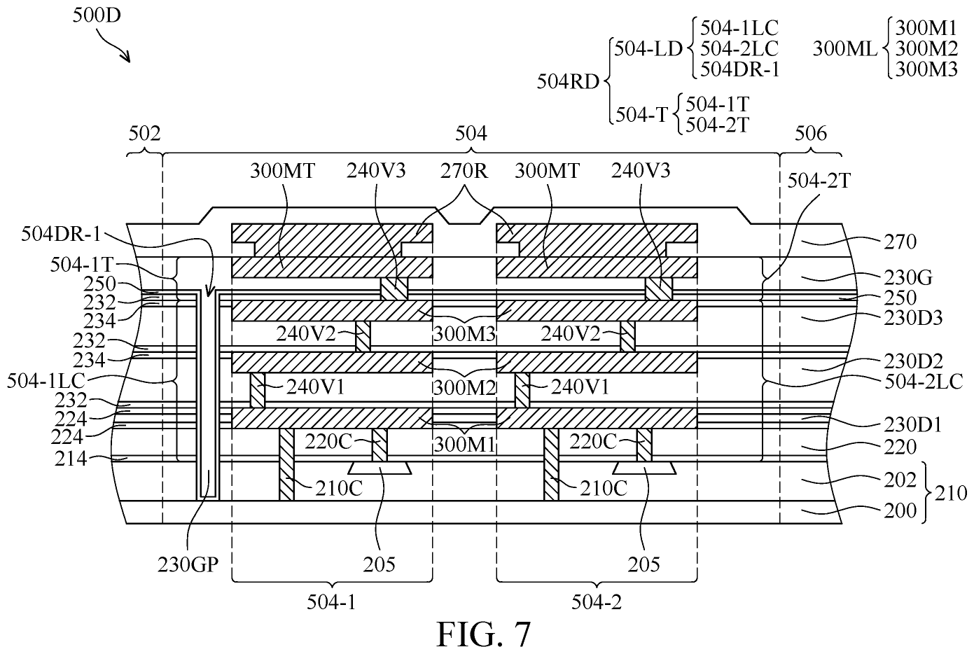

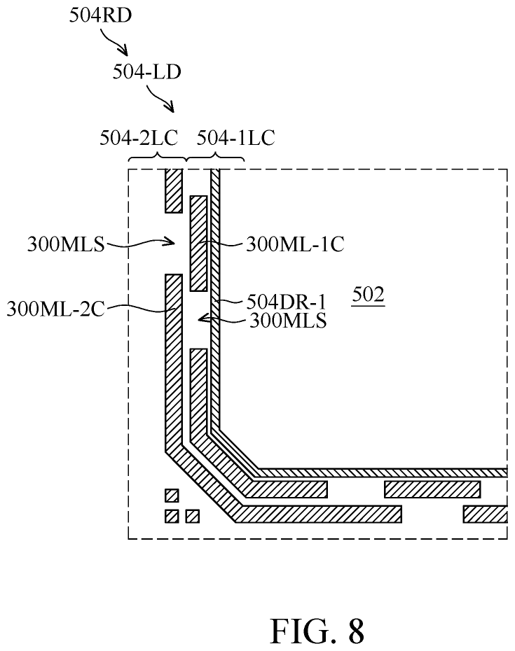

FIG. 7 is a cross-sectional view of the semiconductor device 500D shown along line A-A′ in FIG. 1 in accordance with some embodiments of the disclosure. FIG. 8 is an enlarged view of the region 550 of the semiconductor device 500D in FIGS. 1 and 7 in accordance with some embodiments of the disclosure, showing the layout of a second seal ring portion 504-LD of the seal ring structure 504RD. Elements of the embodiments hereinafter, that are the same or similar as those previously described with reference to FIGS. 1, 2, 3A, 3B and 4-6, are not repeated for brevity. As shown in FIGS. 7 and 8, the difference between the semiconductor devices 500C and 500D is that the semiconductor device 500D includes the second seal ring portion 504-LD directly below the first seal ring portion 504-T shown in FIG. 3A. The second seal ring portion 504-LD includes the conductive layer patterns 300MT including the second patterns 300ML-1C in the second inner ring portion 504-1LC, the second patterns 300ML-2C in the second outer ring portion 504-2LC, and further include a dielectric pattern including the single dielectric seal ring structure 504DR-1 surrounded by the second inner ring portion 504-1LC.

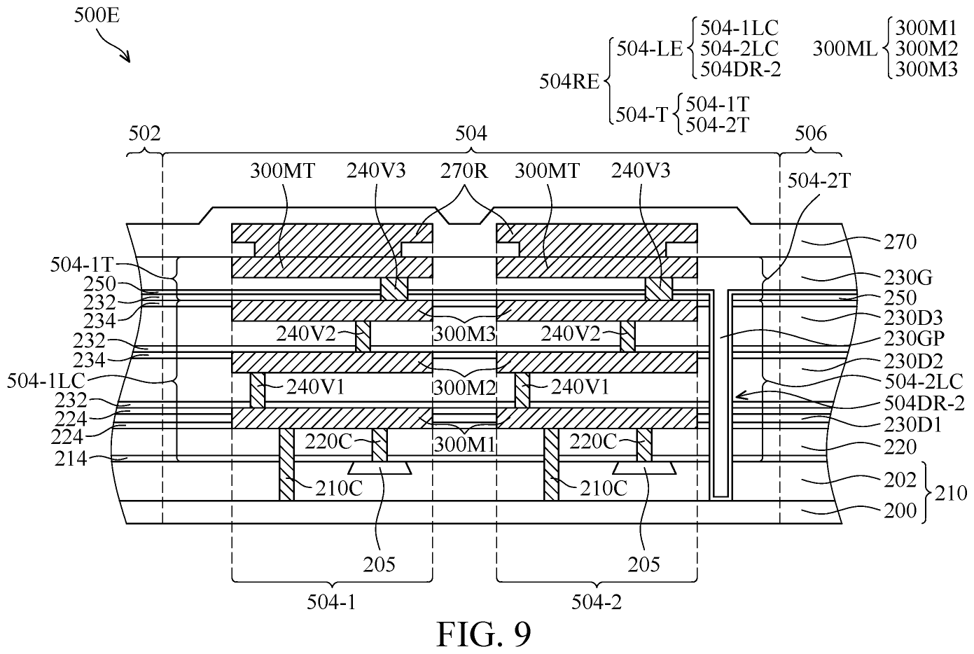

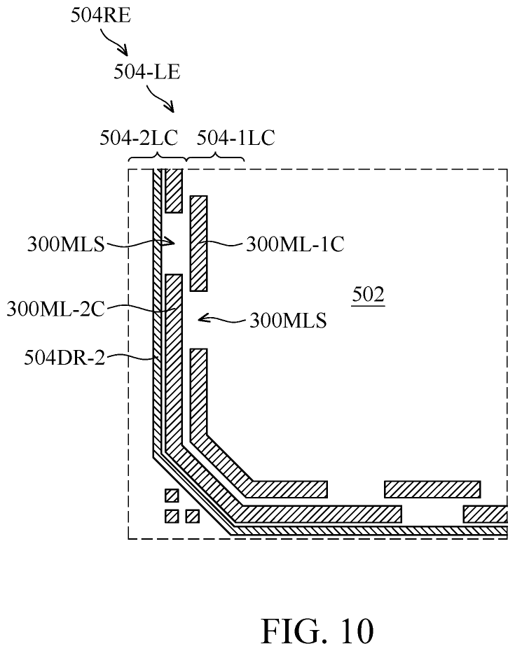

FIG. 9 is a cross-sectional view of the semiconductor device 500E shown along line A-A′ in FIG. 1 in accordance with some embodiments of the disclosure. FIG. 10 is an enlarged view of the region 550 of the semiconductor device 500E in FIGS. 1 and 9 in accordance with some embodiments of the disclosure, showing the layout of a second seal ring portion 504-LE of the seal ring structure 504RE. Elements of the embodiments hereinafter, that are the same or similar as those previously described with reference to FIGS. 1, 2, 3A, 3B and 4-8, are not repeated for brevity. As shown in FIGS. 9 and 10, the difference between the semiconductor devices 500C and 500E is that the semiconductor device 500E includes the second seal ring portion 504-LE directly below the first seal ring portion 504-T shown in FIG. 3A. The second seal ring portion 504-LE includes the conductive layer patterns 300MT including the second patterns 300ML-1C in the second inner ring portion 504-1LC, the second patterns 300ML-2C in the second outer ring portion 504-2LC, and further includes a dielectric pattern including the single dielectric seal ring structure 504DR-2 surrounding the second outer ring portion 504-2LC.

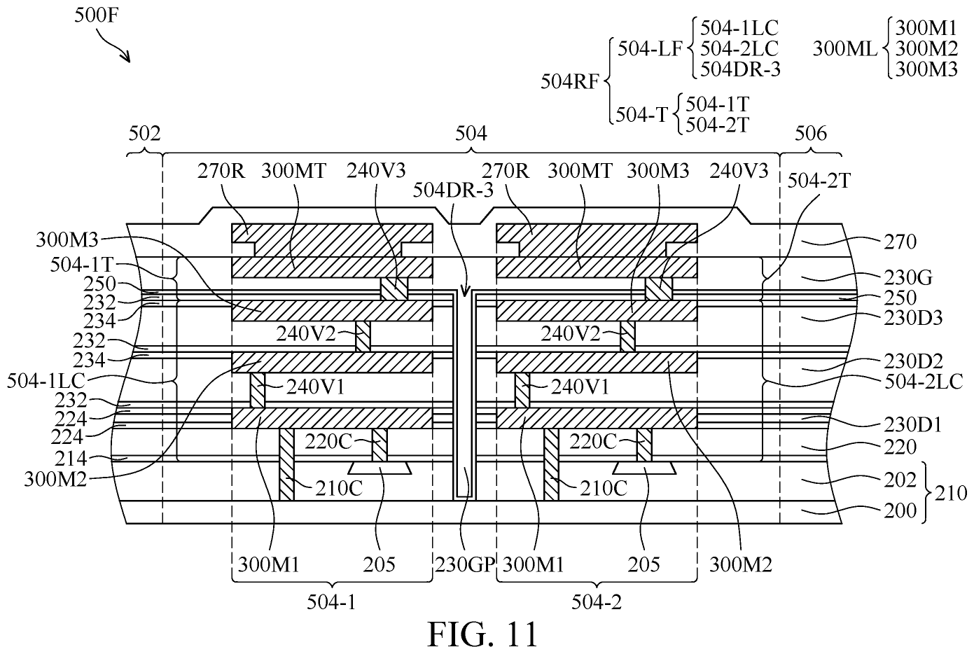

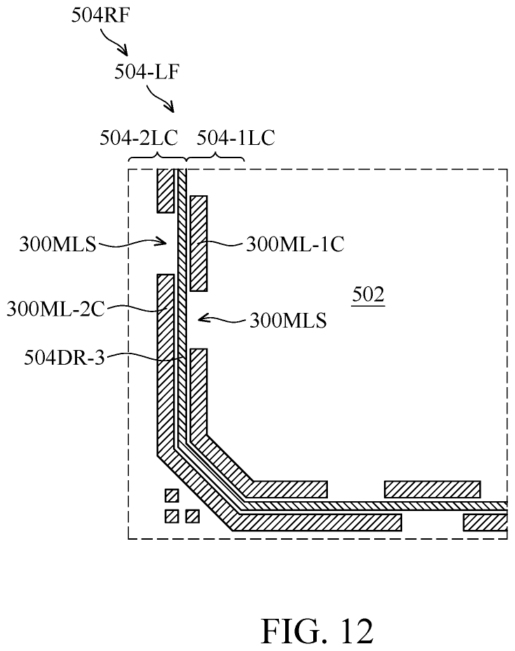

FIG. 11 is a cross-sectional view of the semiconductor device 500F shown along line A-A′ in FIG. 1 in accordance with some embodiments of the disclosure. FIG. 10 is an enlarged view of the region 550 of the semiconductor device 500F in FIGS. 1 and 11 in accordance with some embodiments of the disclosure, showing the layout of a second seal ring portion 504-LF of the seal ring structure 504RF. Elements of the embodiments hereinafter, that are the same or similar as those previously described with reference to FIGS. 1, 2, 3A, 3B and 4-10, are not repeated for brevity. As shown in FIGS. 11 and 12, the difference between the semiconductor devices 500C and 500F is that the semiconductor device 500F includes the second seal ring portion 504-LF directly below the first seal ring portion 504-T shown in FIG. 3A. The second seal ring portion 504-LF includes the conductive layer patterns 300MT including the second patterns 300ML-1C in the second inner ring portion 504-1LC, the second patterns 300ML-2C in the second outer ring portion 504-2LC, and further includes a dielectric pattern including the single dielectric seal ring structure 504DR-3 between the second inner ring portion 504-1LC and the second outer ring portion 504-2LC. In some embodiment, the second outer ring portion 504-2LC surrounds the dielectric seal ring structure 504DR-3, and the dielectric seal ring structure 504DR-3 surrounds the second inner ring portion 504-1LC.

In some embodiment, the first ring portion 504-T and the second seal ring portions 504-LC, 504-LD, 504-LE and 504-LF of the seal ring structures 504RC, 504RD, 504RE and 504RF (also serve as conductive-dielectric composite seal ring structures 504RC, 504RD, 504RE and 504RF) include the conductive layer patterns 300MT including the first (discontinuous) patterns 300MT-1 and 300MT-2 and the second (discontinuous) patterns 300ML-1C and 300ML-2C arranged periodically and discontinuously. The first (discontinuous) patterns 300MT-1 and 300MT-2 may increase the resistance of the first ring portion 504-T of the seal ring structures 504RC, 504RD, 504RE and 504RF embedded in the non low-k dielectric layer (the dielectric layer 230G). In addition, the second (discontinuous) patterns 300ML-1C and 300ML-2C may increase the resistance of the second seal ring portions 504-LC, 504-LD, 504-LE and 504-LF of the seal ring structures 504RC, 504RD, 504RE and 504RF embedded in the low-k dielectric layers (the dielectric layers 220, 230D1, 230D2 and 230D3). In addition, the second seal ring portions 504-LC, 504-LD, 504-LE and 504-LF further include at least one dielectric seal ring pattern, such as the dielectric seal ring structures 504DR-1, 504DR-2 and 504DR-3, surrounding the circuit region 502. Each of the dielectric seal ring structures 504DR-1, 504DR-2 and 504DR-3 is a continuous (closed-loop) dielectric pattern in the top views shown in FIGS. 6, 8, 10 and 12. Each of the dielectric seal ring structures 504DR-1, 504DR-2 and 504DR-3 may serve as a barrier for the second (discontinuous) patterns 300ML-1C and 300ML-2C to further prevent contaminants such as moisture, chemicals, corrosive material or etc. from penetrating into the circuit region 502 and preventing cracks from propagating into the circuit region 502 in the die-sawing process. Therefore, the RF devices (not shown) disposed in the circuit region 502 surrounded by the seal ring structures 504RC, 504RD, 504RE and 504RF has improved RF performances (such as on-resistance (Ron), off-capacitance (Coff), etc.) and prevent moisture and ionic contamination from penetrating the RF devices.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a semiconductor substrate having a circuit region and a seal ring region surrounding the circuit region;
a first dielectric layer disposed over the seal ring region, wherein the first dielectric layer has a first dielectric constant;
a second dielectric layer disposed between the semiconductor substrate and the first dielectric layer, wherein the second dielectric layer has a second dielectric constant that is lower than the first dielectric constant; and
a conductive seal ring structure disposed in the seal ring region, wherein the conductive seal ring structure comprises:
a first seal ring portion embedded in the first dielectric layer, wherein the first seal ring portion comprises first patterns arranged periodically and discontinuously.

2. The semiconductor device as claimed in claim 1, wherein the first seal ring portion comprises:
a first inner ring portion surrounding the circuit region; and
a first outer ring portion surrounding the first inner ring portion, wherein the first patterns of the first inner ring portion and the first outer ring portion are parallel with each other and in a staggered arrangement along the seal ring region.

3. The semiconductor device as claimed in claim 2, wherein the conductive seal ring structure further comprises:
a second seal ring portion disposed directly below the first seal ring portion and embedded in the second dielectric layer.

4. The semiconductor device as claimed in claim 3, wherein the second seal ring portion comprises:
a second inner ring pattern surrounding the circuit region; and
a second outer ring pattern surrounding the second inner ring pattern, wherein each of the second inner ring pattern and the second outer ring pattern has a first width and a second width crossing the seal ring region, wherein the first width is different from the second width.

5. The semiconductor device as claimed in claim 4, wherein each of the second inner ring pattern and the second outer ring pattern comprises:
first regions having the first width; and
second regions alternately arranged with and connected to the first regions, wherein the second regions have the second width.

6. The semiconductor device as claimed in claim 5, wherein the first regions have a first length along the seal ring region, and the second regions have a second length along the seal ring region, wherein the first length is different from the second length.

7. The semiconductor device as claimed in claim 4, wherein each of the second inner ring pattern and the second outer ring pattern has a linear edge and a toothed edge substantially extending along the seal ring region.

8. The semiconductor device as claimed in claim 7, wherein the linear edge of the second inner ring pattern is close to the linear edge of the second outer ring pattern.

9. The semiconductor device as claimed in claim 3, wherein the second seal ring portion comprises:
a second inner ring pattern surrounding the circuit region; and
a second outer ring pattern surrounding the second inner ring pattern, wherein the second inner ring pattern and the second outer ring pattern have the same width.

10. The semiconductor device as claimed in claim 3, wherein the second seal ring portion comprises second patterns arranged periodically and discontinuously, and wherein the second seal ring portion comprises:
a second inner ring portion surrounding the circuit region; and
a second outer ring portion surrounding the second inner ring portion, wherein the second patterns of the second inner ring portion and the second outer ring portion are parallel with each other and in a staggered arrangement along the seal ring region.

11. The semiconductor device as claimed in claim 10, further comprising:
a dielectric seal ring structure disposed in the seal ring region, wherein the dielectric seal ring structure passes through the second dielectric layer but does not pass through the first dielectric layer.

12. The semiconductor device as claimed in claim 11, wherein the dielectric seal ring structure comprises:
a dielectric pillar extending from the first dielectric layer to the semiconductor substrate, wherein the dielectric pillar is a portion of the first dielectric layer; and
a dielectric liner layer surrounding the dielectric pillar and in contact with the semiconductor substrate.

13. The semiconductor device as claimed in claim 12, wherein the dielectric seal ring structure surrounds the second outer ring portion.

14. The semiconductor device as claimed in claim 12, wherein the dielectric seal ring structure is surrounded by the second inner ring portion.

15. The semiconductor device as claimed in claim 12, wherein the second outer ring portion surrounds the dielectric seal ring structure, and the dielectric seal ring structure surrounds the second inner ring portion.

16. The semiconductor device as claimed in claim 12, wherein the dielectric seal ring structure is disposed below the first seal ring portion of the conductive seal ring structure.

17. A semiconductor device, comprising:
a semiconductor substrate having a circuit region and a seal ring region surrounding the circuit region;
a first dielectric layer disposed over the seal ring region, wherein the first dielectric layer has a first dielectric constant;
a second dielectric layer disposed between the semiconductor substrate and the first dielectric layer, wherein the second dielectric layer has a second dielectric constant that is lower than the first dielectric constant;
a first seal ring portion disposed in the seal ring region and embedded in the first dielectric layer, wherein the first seal ring portion comprises first discontinuous patterns in a top view; and
a second seal ring portion disposed in the seal ring region and embedded in the second dielectric layer, wherein the second seal ring portion comprises at least a second continuous pattern in the top view.

18. The semiconductor device as claimed in claim 17, wherein the first seal ring portion comprises:
a first inner ring portion surrounding the circuit region; and
a first outer ring portion surrounding the first inner ring portion, wherein the first discontinuous patterns of the first inner ring portion and the first outer ring portion are parallel with each other and in a staggered arrangement along the seal ring region.

19. The semiconductor device as claimed in claim 17, wherein spaces between the first discontinuous patterns are away form a corner of the seal ring region.

20. The semiconductor device as claimed in claim 17, wherein the second seal ring portion comprises:
a second inner ring pattern surrounding the circuit region; and
a second outer ring pattern surrounding the second inner ring pattern, wherein each of the second inner ring pattern and the second outer ring pattern has a first width and a second width crossing the seal ring region, wherein the first width is different from the second width.

21. The semiconductor device as claimed in claim 20, wherein each of the second inner ring pattern and the second outer ring pattern comprises:
first regions having the first width and a first length along the seal ring region; and
second regions alternately arranged with and connected to the first regions, wherein the second regions have the second width and a second length along the seal ring region, wherein the first length is different from the second length.

22. The semiconductor device as claimed in claim 20, wherein each of the second inner ring pattern and the second outer ring pattern has a linear edge and a toothed edge substantially extending along the seal ring region.

23. The semiconductor device as claimed in claim 22, wherein the toothed edge of the second inner ring pattern is farther away from the toothed edge of the second outer ring pattern than the linear edge of the second outer ring pattern.

24. The semiconductor device as claimed in claim 17, wherein the second seal ring portion comprises:
a second inner ring pattern surrounding the circuit region; and
a second outer ring pattern surrounding the second inner ring pattern, wherein the second inner ring pattern and the second outer ring pattern have the same width.

25. The semiconductor device as claimed in claim 17, wherein the second continuous pattern passes through the second dielectric layer but does not pass through the first dielectric layer.

26. The semiconductor device as claimed in claim 25, wherein the second continuous pattern is composed of:
a dielectric pillar extending from the first dielectric layer to the semiconductor substrate, wherein the dielectric pillar is a portion of the first dielectric layer; and
a dielectric liner layer surrounding the dielectric pillar and in contact with the semiconductor substrate.

27. The semiconductor device as claimed in claim 26, wherein the second seal ring portion comprises:
a second inner ring portion surrounding the circuit region; and
a second outer ring portion surrounding the second inner ring portion, wherein the second inner ring portion and the second outer ring portion are composed of second discontinuous patterns, wherein the second discontinuous patterns in the second inner ring portion and the second outer ring portion are parallel with each other and in a staggered arrangement along the seal ring region.

28. The semiconductor device as claimed in claim 27, wherein the second continuous pattern surrounds the second outer ring portion.

29. The semiconductor device as claimed in claim 27, wherein the second continuous pattern is surrounded by the second inner ring portion.

30. The semiconductor device as claimed in claim 27, wherein the second outer ring portion surrounds the second continuous pattern, and the second continuous pattern surrounds the second inner ring portion.

31. A semiconductor device, comprising:
a semiconductor substrate having a circuit region and a seal ring region surrounding the circuit region;
a first dielectric layer disposed over the seal ring region, wherein the first dielectric layer has a first dielectric constant;
a first seal ring portion disposed in the seal ring region and embedded in the first dielectric layer, wherein the first seal ring portion comprises first discontinuous patterns arranged periodically; and
a second seal ring portion disposed in the seal ring region and between the first dielectric layer and the semiconductor substrate, wherein the second seal ring portion comprises at least one closed-loop pattern.

32. The semiconductor device as claimed in claim 31, further comprising:
a second dielectric layer disposed between the semiconductor substrate and the first dielectric layer, wherein the second dielectric layer has a second dielectric constant that is lower than the first dielectric constant, wherein the second seal ring portion is embedded in the second dielectric layer.

33. The semiconductor device as claimed in claim 32, wherein the first seal ring portion is electrically connected to the second seal ring portion using a via passing through the second dielectric layer.

34. The semiconductor device as claimed in claim 31, wherein the first seal ring portion comprises:
a first inner ring portion surrounding the circuit region; and
a first outer ring portion surrounding the first inner ring portion, wherein the first discontinuous patterns of the first inner ring portion and the first outer ring portion are parallel with each other and in a staggered arrangement along the seal ring region.

35. The semiconductor device as claimed in claim 31, wherein spaces between the first discontinuous patterns are away form a corner of the seal ring region.

36. The semiconductor device as claimed in claim 31, wherein the second seal ring portion comprises:
a second inner closed-loop pattern surrounding the circuit region; and
a second outer closed-loop pattern surrounding the second inner closed-loop pattern, wherein each of the second inner closed-loop pattern and the second outer closed-loop pattern has a first width and a second width crossing the seal ring region, wherein the first width is greater than the second width.

37. The semiconductor device as claimed in claim 36, wherein each of the second inner closed-loop pattern and the second outer closed-loop pattern comprises:
first regions having the first width and a first length along the seal ring region; and
second regions alternately arranged with and connected to the first regions, wherein the second regions have the second width and a second length along the seal ring region, wherein the first length is different from the second length.

38. The semiconductor device as claimed in claim 37, wherein the second regions are disposed corresponding to spaces between the first discontinuous patterns in a top view.

39. The semiconductor device as claimed in claim 31, wherein the second seal ring portion comprises:
a second inner closed-loop pattern surrounding the circuit region; and
a second outer closed-loop pattern surrounding the second inner ring pattern, wherein the second inner ring pattern and the second outer ring pattern have the same width.

40. The semiconductor device as claimed in claim 31, wherein the closed-loop pattern passes through the second dielectric layer and is composed of:
a dielectric pillar extending from the first dielectric layer to the semiconductor substrate, wherein the dielectric pillar is a portion of the first dielectric layer; and
a dielectric liner layer surrounding the dielectric pillar and in contact with the semiconductor substrate.

41. The semiconductor device as claimed in claim 40, wherein the second seal ring portion comprises:
a second inner ring portion surrounding the circuit region; and
a second outer ring portion surrounding the second inner ring portion, wherein the second inner ring portion and the second outer ring portion are composed of second discontinuous patterns.

42. The semiconductor device as claimed in claim 41, wherein the closed-loop pattern surrounds the second outer ring portion.

43. The semiconductor device as claimed in claim 41, wherein the closed-loop pattern is surrounded by the second inner ring portion.

44. The semiconductor device as claimed in claim 41, wherein the second outer ring portion surrounds the closed-loop pattern, and the closed-loop pattern surrounds the second inner ring portion.
